(19) United States
(12) Patent Application Publication
(10) Pub. No.: US 2011/0020547 A1
(43) Pub. Date: Jan. 27, 2011

(54) HIGH DIELECTRIC CONSTANT FILMS DEPOSITED AT HIGH TEMPERATURE BY ATOMIC LAYER DEPOSITION

(76) Inventors: Julien GATINEAU, Ibaraki (JP); Cheol Seong Hwang, Seoul (KR); Sang Woon Lee, Seoul (KR)

Correspondence Address: American Air Liquide, Inc.;Intellectual Property Dept., 2700 Post Oak Boulevard, Suite 1800, Houston, TX, 77056, US

(21) Appl. No.: 12/506,903

(22) Filed: Jul. 21, 2009

(51) Int. Cl. C23C 16/06; H01B 3/02

(52) U.S. Cl. 427/255.28; 252/572

(57) ABSTRACT

Methods and compositions for depositing a film on one or more substrates include providing a reactor with at least one substrate disposed in the reactor. At least one alkaline earth metal precursor and at least one titanium containing precursor are provided, vaporized, and at least partly deposited onto the substrate to form a strontium and titanium or a strontium and titanium and barium containing film.

### BACKGROUND

1. Field of the Invention

This invention relates generally to compositions, methods and apparatus for use in the manufacture of semiconductor, photovoltaic, LCF-TFT, or flat panel type devices.

2. Background of the Invention

New dielectric thin films which have as a material property a high dielectric constant (“high-k films”) are becoming more necessary, as the overall device size decreases in the manufacture of semiconductor, photovoltaic, flat panel, or LCD-TFT type devices. High-k films are particularly useful to form capacitors, which may store and discharge electrical charge for the device.

High-k films are normally formed and/or deposited onto a substrate using the well known chemical vapor deposition (CVD) or Atomic Layer Deposition (ALD) manufacturing processes. There are many variations of the CVD and ALD processes but generally, these methods involve the introduction of at least one precursor (which contains the atoms desired to be deposited) into a reactor, where the precursor then reacts and/or decomposes onto a substrate in a controlled fashion, to form a thin film.

While numerous materials have been investigated to form high-k films through CVD or ALD methods, alkaline earth metal, particularly strontium and/or barium, based precursors show promise when coupled with titanium (to obtain films such as, for example, STO (strontium titanium oxide SrTiO₃), BST (barium strontium titanium oxide, (Ba,Sr)TiO₃). Most alkaline earth metal precursors can be characterized has having low vapor pressure, and high melting points (e.g. solid at room temperature), and very low volatility. These properties can lead to difficulty in delivering the precursors to the reactor, as the solid precursors may clog the supply lines or the vaporizers.

The type of films with high dielectric constant (“High-k” films) or “super High-k” films (with dielectric constant above 100) that are normally desirable are, among others, TiO₂, STO (strontium titanium oxide SrTiO₃), BST (barium strontium titanium oxide, (Ba,Sr)TiO₃, SBT (strontium bismuth titanium oxide, SrBi₂Ti₃O₁₂), PZT (lead zirconium titanium oxide, Pb(Zr,Ti)O₃). In ALD process, high temperature is preferred to obtain a suitable layer morphology, film quality, low leakage current, high dielectric constant and controlled cationic ratio, such as Sr:Ti for STO films.

The number of strontium and barium precursors available for vapor deposition is scarce. In the case of strontium, one can mention Sr(Cp*)₂ and Sr(dmp)₂, whose chemical formulas are Sr((CH₃)₅C₅)₂ and Sr(C₁₁H₁₉O₂)₂, respectively. These precursors are solid with a high melting point (above 200° C.), but their vapor pressure is low, especially for the latter, which generates throughput and equipment issues. The stability of the latter is also a problem because the temperature at which the precursor reacts with an oxidizing agent corresponds to its decomposition temperature.

Solvents commonly utilized in precursor solutions, such as tetrahydrofurane (THF), are not necessarily compatible with the extreme low volatility of the alkaline earth metal precursors, and when they are used, the solvents will quickly vaporize before the precursor, easily reaching the solubility limit and leading to condensation of the precursor in the reactor inlet, or clogging of the vaporizer.

Consequently, there exists a need deposition processes and materials that allow for and increased deposition temperature used in making strontium containing films, such as STO or BST, which when made at higher temperatures, should result in higher quality films.

### BRIEF SUMMARY

Embodiments of the invention provide novel methods and compositions for the deposition of a film on a substrate. In general, the disclosed compositions and methods utilize an alkaline earth metal precursor (strontium and/or barium) and a titanium precursor, where the precursors are provided pure or diluted in an aromatic solvent or solvent mixture.

In an embodiment, a method for depositing a film on one or more substrates comprises providing a reactor with at least one substrate disposed in the reactor. At least one alkaline earth metal precursor and at least one titanium precursor, each either pure or dissolved in a solvent or solvent mixture, are provided. The alkali earth metal precursor has the general formula:

M(RₘCp)₂Lₙ (I)

wherein M is either strontium or barium; each R is either H or a C1-C4 linear, branched, or cyclic alkyl group; L is a Lewis base; m is 2, 3, 4, or 5; and n is 0, 1, or 2. The titanium precursor has one of the following general formulas:

Ti(OR)₂X₂ (II)

Ti(O)X₂ (III)

Ti(R′_{y}Cp)(OR″)₃ (IV)

wherein each R, R′, R″ is independently selected from H or a C1-C4 linear, branched, or cyclic alkyl group; X is a β-diketonate ligand, substituted or not on all the available substitution sites, each substitution site independently being substituted by one of a C1-C4 linear, branched, or cyclic alkyl group, or a C1-C4 linear, branched, or cyclic fluoroalkyl group (totally fluorinated or not); and y is one of 1, 2, 3, 4, or 5. At least part of the alkaline earth metal precursor and the titanium precursor are vaporized, either together or singularly, to form alkaline earth metal and titanium precursor vapor solutions. At least part to the precursor vapor solutions are introduced into the reactor, and at least part of these are then deposited onto the substrate to form a strontium and titanium or a strontium and titanium and barium containing film.

In an embodiment, a composition comprises at least one alkaline earth metal precursor and at least one titanium precursor, each either dissolved or not in a solvent or solvent mixture. The alkali earth metal precursor has the general formula:

M(RₘCp)₂Lₙ (I)

wherein M is either strontium or barium; each R is either H or a C1-C4 linear, branched, or cyclic alkyl group; L is a Lewis base; m is 2, 3, 4, or 5; and n is 0, 1, or 2. The titanium precursor has one of the following general formulas:

Ti(OR)₂X₂ (II)

Ti(O)X₂ (III)

Ti(R′_{y}Cp)(OR″)₃ (IV)

wherein each R, R′, R″ is independently selected from H or a C1-C4 linear, branched, or cyclic alkyl group; X is a β-diketonate ligand, substituted or not on all the available substitution sites, each substitution site independently being substituted by one of a C1-C4 linear, branched, or cyclic alkyl group, or a C1-C4 linear, branched, or cyclic fluoroalkyl group (totally fluorinated or not); and y is one of 1, 2, 3, 4, or 5. The solvent or solvent mixture is an aromatic solvent with at least one aromatic ring, and which has a boiling point greater than the melting point of the alkaline earth metal or titanium precursor which is dissolved therein.

Other embodiments of the current invention may include, without limitation, one or more of the following features:
the solvent comprises an aromatic solvent of the general formula

CₐR_{b}N_{c}O_{d}
wherein each R is independently selected from: H; a C1-C6 linear, branched, or cyclic alkyl or aryl group; an amino substituent such as NR¹R² or NR¹R²R³, where R¹, R² and R³ are independently selected from H, and a C1-C6 linear, branched, or cyclic alkyl or aryl group; and an alkoxy substituent such as OR⁴, or OR⁵R⁶ where R⁴, R⁵ and R⁶ are independently selected from H, and a C1-C6 linear, branched, or cyclic alkyl or aryl group;
   a is 4 or 6;
   b is 4, 5, or 6;
   c is 0 or 1; and
   d is 0 or 1;
the aromatic solvent is selected from one of toluene; mesitylene; phenetol; octane; xylene; ethylbenzene; propylbenzene; ethyltoluene; ethoxybenzene; pyridine; and mixtures thereof;
the Lewis base is selected from one of tetrahydrofuran (THF); dioxane; dimethoxyethane, diethoxyethane; and pyridine;
an oxidizing gas is introduced into the reactor, and the oxidizing gas is reacted with at least part of the precursor vapor solutions, prior to or concurrently with the deposition of at least part of the precursor vapor solutions onto the substrate;
the reaction gas is ozone, its radical species, or an ozone containing mixtures;
the deposition is either a chemical vapor deposition (CVD) or an atomic layer deposition (ALD);
the deposition is performed at a temperature between about 50° C. and about 600° C., preferably between about 200° C. and about 500° C.;
the deposition is performed at a pressure between about 0.0001 Torr and about 1000 Torr, preferably between about 0.1 Torr and about 10 Torr;
the strontium precursor is selected from one of: Sr(iPr₃Cp)₂; Sr(iPr₃Cp)₂(THF); Sr(iPr₃Cp)₂(THF)₂; Sr(iPr₃Cp)₂(dimethylether); Sr(iPr₃Cp)₂(dimethylether)₂; Sr(iPr₃Cp)₂(diethylether); Sr(iPr₃Cp)₂(diethylether)₂; Sr(iPr₃Cp)₂(dimethoxyethane); Sr(iPr₃Cp)₂(dimethoxyethane)₂; Sr(tBu₃Cp)₂; Sr(tBu₃Cp)₂(THF); Sr(tBu₃Cp)₂(THF)₂; Sr(tBu₃Cp)₂(dimethylether); Sr(tBu₃Cp)₂(dimethylether)₂; Sr(tBu₃Cp)₂(diethylether); Sr(tBu₃Cp)₂(diethylether)₂; Sr(tBu₃Cp)₂(dimethoxyethane); and Sr(tBu₃Cp)₂(dimethoxyethane)₂;
the barium precursor is selected from one of: Ba(iPr₃Cp)₂; Ba(iPr₃Cp)₂(THF); Ba(iPr₃Cp)₂(THF)₂; Ba(iPr₃Cp)₂(dimethylether); Ba(iPr₃Cp)₂(dimethylether)₂; Ba(iPr₃Cp)₂(diethylether); Ba(iPr₃Cp)₂(diethylether)₂; Ba(iPr₃Cp)₂(dimethoxyethane); Ba(iPr₃Cp)₂(dimethoxyethane)₂; Ba(tBu₃Cp)₂; Ba(tBu₃Cp)₂(THF); Ba(tBu₃Cp)₂(THF)₂; Ba(tBu₃Cp)₂(dimethylether); Ba(tBu₃Cp)₂(dimethylether)₂; Ba(tBu₃Cp)₂(diethylether); Ba(tBu₃Cp)₂(diethylether)₂; Ba(tBu₃Cp)₂(dimethoxyethane); and Ba(tBu₃Cp)₂(dimethoxyethane)₂;
the titanium precursor is selected from one of: Ti(OMe)₂(acac)₂; Ti(OEt)₂(acac)₂; Ti(OPr)₂(acac)₂; Ti(OBu)₂(acac)₂; Ti(OMe)₂(tmhd)₂; Ti(OEt)₂(tmhd)₂; Ti(OPr)₂(tmhd)₂; Ti(OBu)₂(tmhd)₂; TiO(acac)₂; TiO(tmhd)₂; Ti(Me₅Cp)(OMe)₃; Ti(MeCp)(OMe)₃; and
a strontium and titanium or a strontium and barium and titanium containing thin film coated substrate.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to particular system components. This document does not intend to distinguish between components that differ in name but not function. Generally as used herein, elements from the periodic table of elements have been abbreviated with their standard abbreviation (e.g. Ti=titanium, Ba=barium, Sr=strontium, etc).

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me” refers to a methyl group; the abbreviation, “Et” refers to an ethyl group; the abbreviation, “Pr” refers to a propyl group; the abbreviation, “iPr” refers to an isopropyl group; the abbreviation “Bu” refers to butyl (n-butyl); the abbreviation “tBu” refers to tert-butyl; the abbreviation “sBu” refers to sec-butyl; the abbreviation, “OMe,” refers to a methoxy group; the abbreviation, “OEt” refers to an ethoxy group; the abbreviation, “OPr” refers to a propoxy group; the abbreviation, “OiPr” refers to an isopropoxy group; the abbreviation “OBu” refers to butoxy (n-butyl); the abbreviation “OtBu” refers to tert-butoxy; the abbreviation “OsBu” refers to sec-butoxy; the abbreviation “acac” refers to acetylacetonato; the abbreviation “tmhd” refers to 2,2,6,6-tetramethyl-3,5-heptadionato; the abbreviation “Cp” refers to cyclopentadienyl; the abbreviation “Cp*” refers to pentamethylcyclopentadienyl.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 illustrates graphical deposition data according to one embodiment of the current invention;

FIG. 2 illustrates additional graphical deposition data according to one embodiment of the current invention;

FIG. 3 illustrates additional graphical deposition data according to one embodiment of the current invention; and

FIG. 4 illustrates the step-coverage of a deposition process according to one embodiment of the current invention.

### DESCRIPTION OF PREFERRED EMBODIMENTS

Embodiments of the present invention provide novel methods and compositions for the deposition of a film on a substrate. In general, the disclosed compositions and methods utilize a precursor mixture of an alkaline earth metal precursor and a titanium precursor.

In some embodiments, a strontium and/or barium precursor, provided pure or diluted in a solvent, is provided to a reactor for deposition onto a substrate, together with a titanium precursor, provided pure or diluted in a solution. The possibility to use the precursors mixed together, pure or diluted in a solution, in which the concentration of the precursors is in the range (excluding the eventual solvent) 5 to 95%, is also considered. Proper combinations of the precursors and solvents may ensure smooth delivery and prevent clogging of the distribution system vaporizer or supply line from the vaporization of the solution. In particular, by combining the precursors with a solvent which has a boiling point greater than the melting point of the precursor which exhibits the highest melting point of the used precursors (where the vaporization point of the solvent is also greater than that of the alkaline earth precursor) such distribution problems may be reduced or limited, as there will be little to no condensation or agglomeration of the solid in the feed lines, the vaporizer, or the inlet to the reactor.

In some embodiments, the alkaline earth metal precursor may have one of the general formulas:

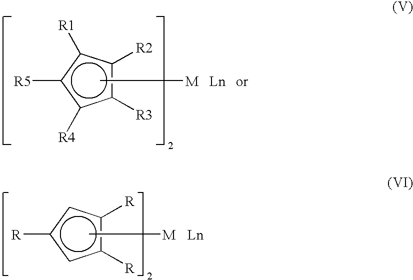

wherein M is strontium or barium, each R is independently selected from H, Me, Et, n-Pr, i-Pr, n-Bu, or t-Bu; n is 0, 1, or 2; and L is an oxygen, nitrogen or phosphorus containing Lewis base.

In some embodiments, the titanium precursor may have one of the general formulas:

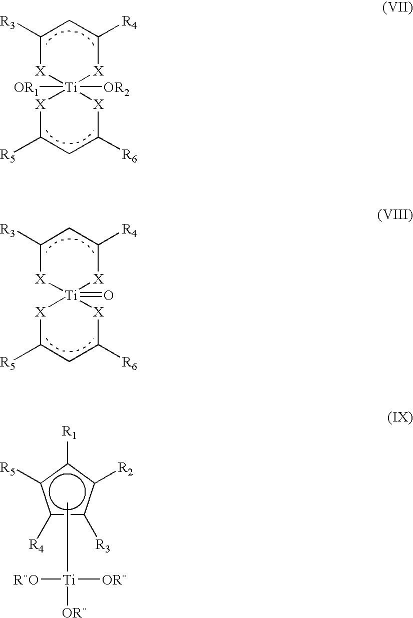

wherein each X is independently selected from one of O and N; each R is independently selected from H, Me, Et, n-Pr, i-Pr, n-Bu, t-Bu, s-Bu, or their fluoro version.

In some embodiments, the titanium precursor is one which enables titanium oxide depositions in ALD mode at temperatures higher than 250 C, more preferably above 300 C.

In some embodiments, the titanium precursor is bis(tmhd)bis(iso-propoxy) titanium, as shown below:

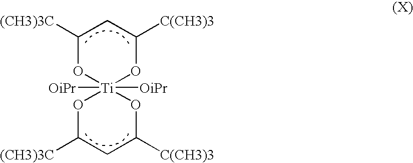

In some embodiments, the titanium precursor is (pentamethylcyclopentadienyl)(tri-methoxy) titanium, as shown below:

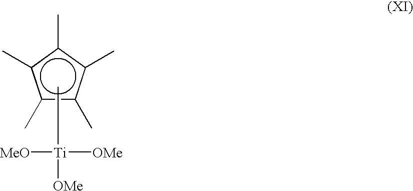

In some embodiments, the solvent is an aromatic solvent characterized in that the solvent has at least one aromatic ring. In a particular embodiment, it has been determined that aromatic molecules are particularly suitable as solvents for the alkaline earth precursor (strontium and/or barium) and/or the titanium precursor, in terms of solubility while having a vaporization temperature greater than that of tetrahydrofurane or pentane.

In some embodiments, the aromatic solvent may be one of the following:

TABLE 1
Examples of solvents

| | | | | Viscosity |
|---|---|---|---|---|
| | Formula | b.p. | Density | [cP] |
| Name | (F.W.) | [C.] | [g/cm3] | @25 C. |
| Octane | C₈H₈ (114.23) | 125 | 0.7 | 0.51 |
| Toluene | C₆H₅CH₃ (92.14) | 111 | 0.87 | 0.54 |
| Xylene | C₆H₄(CH₃)₂ (106.16) | 138.5 | 0.86 | 0.6 |
| Mesitylene | C₆H₃(CH₃)₃ (120.2) | 165 | 0.86 | 0.99 |
| Ethylbenzene | C₆H₅C₂H₅ (106.17) | 136 | 0.87 | 0.67 |
| Propylbenzene | C₆H₅C₃H₇ (120) | 159 | 0.86 | 0.81 |
| Ethyl toluene | C₆H₄(CH₃)(C₂H₅) (120.19) | 160 | 0.86 | 0.63 |
| Ethoxybenzene | C₆H₅OC₂H₅ (122.17) | 173 | 0.96 | 1.1 |
| Pyridine | C₅H₅N (79.1) | 115 | 0.98 | 0.94 |

In some embodiments, the list of solvents that can potentially be used for the titanium molecule can be broadened to include any type of solvents known by those skilled in the art and that are usually used for such applications, for example THF.

In some embodiments, the alkaline earth metal precursor and/or the titanium precursor are provided diluted in an aromatic solvent, or in a mixture of aromatic solvents, such aromatic solvent(s) has at least one aromatic ring, and has a greater boiling point than the melting point of the alkaline earth metal precursor (strontium and/or barium) and/or the titanium precursor. It is also considered that the alkaline earth metal precursor and titanium precursors can be provided together, with or without solvents. The liquid precursor solution(s) is vaporized to form a precursor solution vapor, and the vapor is introduced into the reactor. At least part of the vapor is deposited onto the substrate to form an alkaline earth metal containing film.

The disclosed precursors, in solvent solution or not, may be deposited to form a thin film using any deposition methods known to those of skill in the art. Examples of suitable deposition methods include without limitation, conventional CVD, low pressure chemical vapor deposition (LPCVD), plasma enhanced chemical vapor depositions (PECVD), atomic layer deposition (ALD), pulsed chemical vapor deposition (P-CVD), plasma enhanced atomic layer deposition (PE-ALD), or combinations thereof.

In an embodiment, the precursors are introduced into a reactor in vapor form. The precursor in vapor form may be produced by vaporizing a liquid precursor solution, through a conventional vaporization step such as direct vaporization, distillation, or by bubbling an inert gas (e.g. N₂, He, Ar, etc.) into the precursor solution and providing the inert gas plus precursor mixture as a precursor vapor solution to the reactor. Bubbling with an inert gas may also remove any dissolved oxygen present in the precursor solution.

The reactor may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates on to which the thin films will be deposited. The one or more substrates may be any suitable substrate used in semiconductor, photovoltaic, flat panel or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium or gold) may be used. The substrate may also have one or more layers of differing materials already deposited upon it from a previous manufacturing step.

In some embodiments, in addition to the precursors, a reactant gas may also be introduced into the reactor. In some embodiments, the reaction gas is ozone, radical species of ozone, or any ozone containing mixture. In some embodiments, the precursors vapor solution(s) and the reaction gas may be introduced sequentially (as in ALD) or simultaneously (as in CVD) into the reactor. The use of ozone rather than any other oxidizing (e.g. H₂O) agent is recommended in order to obtain a process of films with superior properties. Such properties include: ALD window (ALD at higher temperature), and films with lower leakage current.

In some embodiments, and depending on what type of film is desired to be deposited, additional precursors may be introduced into the reactor. These additional precursors comprise another metal source, such as copper, praseodymium, manganese, ruthenium, titanium, tantalum, bismuth, zirconium, hafnium, lead, niobium, magnesium, aluminum, lanthanum, or mixtures of these. In embodiments where a additional metal containing precursors are utilized, the resultant film deposited on the substrate may contain multiple different metal types. The additional metal containing precursors may be added to the deposition processes in a similar manner as described for the titanium and alkaline earth metal precursors. The addition of these additional metal containing precursors may be used to tune the composition of the strontium and titanium or strontium and titanium and barium containing films. In some embodiments, bismuth, lead, and zirconium containing precursors are particularly useful for this.

The first precursor and any optional reactants or precursors may be introduced sequentially (as in ALD) or simultaneously (as in CVD) into the reaction chamber. In some embodiments, the reaction chamber is purged with an inert gas between the introduction of the precursor and the introduction of the reactant. In one embodiment, the reactant and the precursor may be mixed together to form a reactant/precursor mixture, and then introduced to the reactor in mixture form. In some embodiments, the reactant may be treated by a plasma, in order to decompose the reactant into its radical form, In some of these embodiments, the plasma may generally be at a location removed from the reaction chamber, for instance, in a remotely located plasma system. In other embodiments, the plasma may be generated or present within the reactor itself. One of skill in the art would generally recognize methods and apparatus suitable for such plasma treatment.

Depending on the particular process parameters, deposition may take place for a varying length of time. Generally, deposition may be allowed to continue as long as desired or necessary to produce a film with the necessary properties. Typical film thicknesses may vary from several hundred angstroms to several hundreds of microns, depending on the specific deposition process. The deposition process may also be performed as many times as necessary to obtain the desired film.

In some embodiments, the temperature and the pressure within the reactor are held at conditions suitable for ALD or CVD depositions. For instance, the pressure in the reactor may be held between about 0.0001 and 1000 Torr, or preferably between about 0.1 and 10 Torr, as required per the deposition parameters. Likewise, the temperature in the reactor may be held between about 50 and 600 C, preferably between 200 and 500 C.

In some embodiments, the precursors vapor solution(s) and the reaction gas, may be pulsed sequentially or simultaneously (e.g. pulsed CVD) into the reactor. Each pulse of precursor and may last for a time period ranging from about 0.01 s to about 10 s, alternatively from about 0.3 s to about 3 s, alternatively from about 0.5 s to about 2 s. In another embodiment, the reaction gas may also be pulsed into the reactor. In such embodiments, the pulse of each gas may last for a time period ranging from about 0.01 s to about 10 s, alternatively from about 0.3 s to about 3 s, alternatively from about 0.5 s to about 2 s.

### EXAMPLES

The following non-limiting examples are provided to further illustrate embodiments of the invention. However, the examples are not intended to be all inclusive and are not intended to limit the scope of the inventions described herein.

### Example 1

Sr(iPr₃Cp)₂(THF)₂ can be dissolved in toluene, xylene, mesitylene, ethoxybenzene, propylbenzene with high solubility (over 0.1 mol/L) at room temperature. This strontium precursor's vapor pressure is above 1 Torr at 180° C. and its melting point is 94° C. THF's boiling point is below and has been found to lead to polymerization near the vaporization point. The boiling point of each of these solvents is higher than the melting point of the strontium precursor. This combination can make liquid delivery smooth and prevent from clogging by vaporization of solvent in supply line and vaporizer.

### Example 2

### SrO₂ Depositions in ALD Mode Using Sr(CpiPr₃)₂ Together with H₂O or O₃ as Co-Reactant

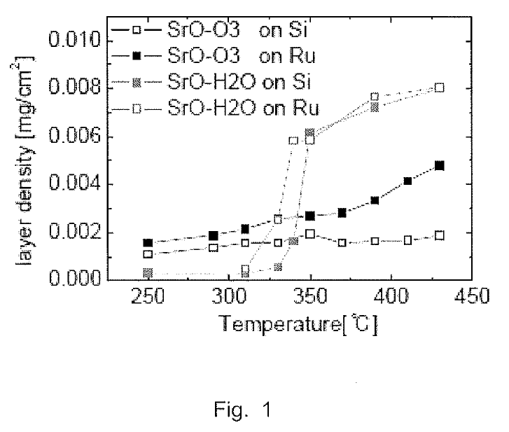

A 200 mm single wafer chamber was used to deposit SrO₂ films using Sr(CpiPr₃)₂. Sr(CpiPr₃)₂ was stored in a canister and heated at 100° C. to allow the melting of the molecule. All the distribution lines were heated at 110° C. up to the reaction chamber where the precursors' vapor and co-reactant were introduced sequentially (ALD mode). At first, H₂O was used as a co-reactant. The influence of the pulse length of the precursor and co-reactant was verified using 3 sec of Sr(CpiPr₃)₂ and 2 sec of H₂O, each followed respectively by 5 sec nitrogen pulses (for purge). As can be seen on FIG. 1 showing the profile of the film growth rate (coupled with the layer density) depending on the deposition temperature, decomposition occurs from 330-340° C. when H₂O is used as a co-reactant, as the deposition rate suddenly increases. When H₂O is substituted by ozone, the increase is not observed up to 390° C.

While not being limited to theory, it is believed that this means that using ozone enables to increase the maximum ALD temperature by 60° C. compare to the H₂O case. Also, the deposition rate decreased by more than half in the case of ozone.

It is believed that such behavior is explained by the fact that H₂O reacts with the Cp ligand and leaves a hydroxyl bond present on the surface of the layer. The current reaction is believed to take place during the precursor pulse (example on —OH terminated Si wafer):

Si—OH+Sr(CpiPr₃)₂→Si—O—Sr(CpiPr₃)(s)+HCp(iPr)₃(g)

During the H₂O pulse, the reaction is expected to be:

O—Sr(CpiPr₃)(s)+H₂O→O—Sr—OH(s)+HCp(iPr)₃(g)

And such cycle will repeat itself during the ALD process.

Cp is very reactive towards the hydroxyl bond, leading to a high deposition process and “low” maximal ALD upper window.

In the case of ozone ALD, the reaction mechanism is very different.

Assuming that the vapors of the first pulse are introduced on the same surface, the half-reaction during the precursor pulse is the same (example on —OH terminated Si wafer):

Si—OH+Sr(CpiPr₃)₂→Si—O—Sr(CpiPr₃)(s)+HCp(iPr)₃(g)

However, during the O₃ pulse, due to the high oxidizing power of ozone, the reaction is expected to be:

O—Sr(CpiPr₃)(s)+O₃→O—Sr—O*(s)+O—Sr*(s)+by-products (g)

The by-products being H₂O, COx, hydrocarbons, etc.

The Sr ions would then react with either the produced H₂O to produce Sr(OH)₂, or with the oxygen atoms or O₃ molecules to form SrO.

It is believed that the latter reaction is favored vs. Sr(OH)₂ formation. During the next step of strontium pulse, the precursor's vapors may react with the excess oxygen ions on the surface, or the Sr ions of the precursor may directly bond chemically to the O ions of the grown SrO film.

It seems that when using ozone, the O species present on the surface are able to stabilize the adsorbed strontium due to the generation of more Sr—O bonds than in the case of H₂O. Sr being bonded to more O in the surface, the surface itself is in a more stable condition, explaining the lower reactivity towards upcoming strontium pulse and the lower deposition rate.

It is concluded that the use of ozone has advantages vs. H₂O for the deposition of strontium oxide films as such films can be deposited in ALD conditions at higher temperatures. This generally allows obtaining higher quality films.

Films deposited at 370 C exhibited low leakage current.

### Example 3

### SrTiO₃ (STO) Deposition Using Sr(CpiPr₃)₂ and H₂O and Ti(tmhd)₂(OiPr)₂ and O₃

Vapors of a titanium precursor, as well as the ozone needed for its ALD process, were added to example 2. The selected titanium precursor is Ti(tmhd)₂(OiPr)₂.

The introduction pattern was as such: (titanium-purge-ozone-purge)₅-strontium-purge-water-purge-, and such scheme was repeated as much as desired (the titanium pulse was repeated 5 times for 1 strontium pulse). The ALD of the titanium precursors with ozone was already verified previously and the same saturation parameters were used for this test.

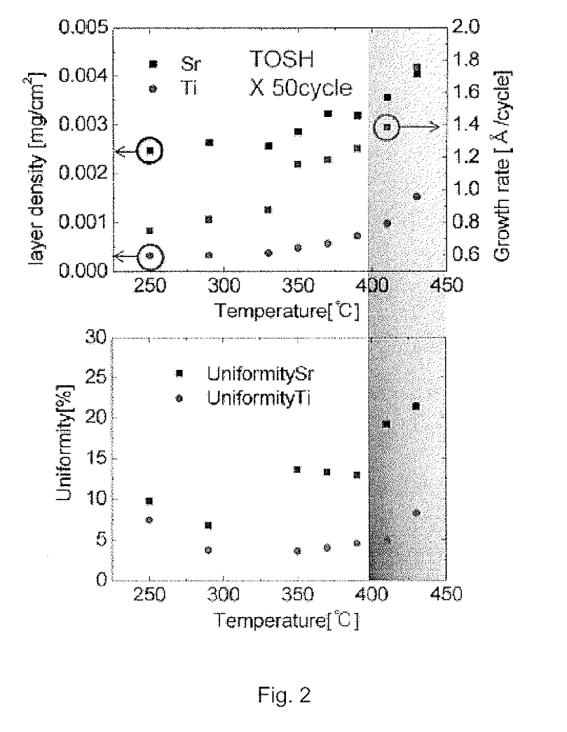

Results obtained for STO depositions were very similar to those obtained in example 2. The maximal deposition temperature was around 390° C. Above 390° C., the growth rate of the STO film, as well as the non-uniformity of the layer within the wafer started to increase, as showed in FIG. 2.

This can be explained as the oxidizing pulse prior to strontium is ozone, and so the same surface species will be present during the introduction of the strontium precursor's vapors, leading to same results as example 2 (ozone case).

It is noted that, that the strontium layer density came back to similar values obtained in example 2 (ozone case). This may confirm the role of the presence of O ions instead of hydroxyl bonds onto the surface when the vapors of the strontium precursors are introduced.

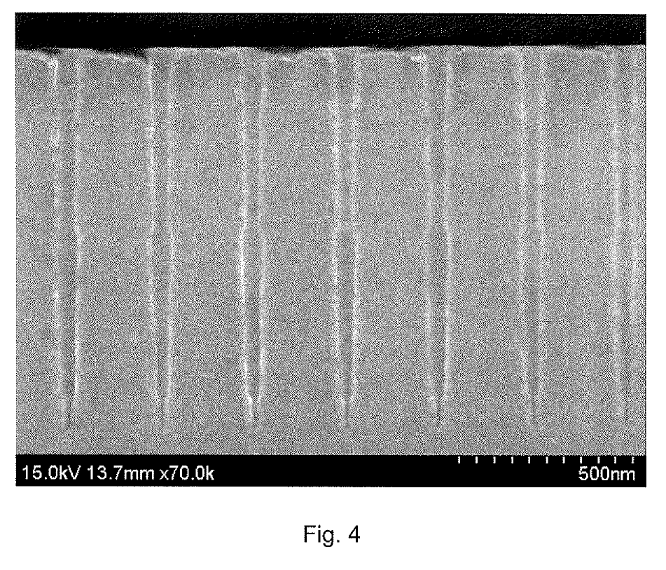

The saturation characteristic of the ALD regime could also be verified by making thin film deposition in deep holes and check the uniformity of the films. FIG. 4 shows the results in a 10:1 hole of 108 nm diameter. The step coverage is above 90% for a ˜15 nm film, even at temperature as high as 370° C.

### Example 4

### SrTiO₃ (STO) Deposition Using Sr(CpiPr₃)₂, Ti(tmhd)₂(OiPr)₂ and O₃ for Both Precursors

The tests were performed in the same conditions as in example 4, using ozone as co-reactant for both strontium and titanium precursors. In this case, the ALD window and its characteristic saturation regime could also be observed up to 390° C.

The deposition rate was slightly lower compared to example 3, which confirms the previous data and statements.

### Example 5

### Influence of Substrates on STO Film Formation

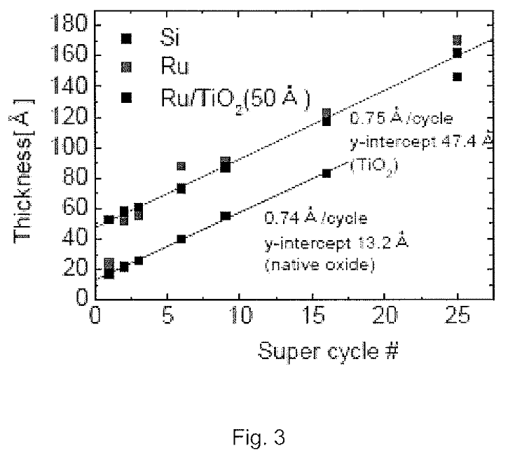

STO depositions were performed with ozone as co-reactant for the titanium precursor and water as co-reactant for the strontium precursor. The selected substrates were wafers of silicon, ruthenium and 50 Å TiO₂ layer on ruthenium. Layer density measurements are showed on FIG. 3. After a few cycles, the deposition speed is the same for each substrate. However, the nucleation on ruthenium reveals that there is a drastic change after the first cycle. The thickness of the STO layer after one cycle is almost similar to the Si substrate case. But from 2 cycles, the thickness of the film is similar to the TiO₂ sub-layer. A look at FIG. 1 enables to see that the deposition of SrO on ruthenium using ozone is more than 50% higher in the case of ozone vs. H₂O. It is believed that in both case (H₂O or O₃), the ruthenium wafer is oxidized to RuO₂ in rutile phase, which is similar to the TiO₂ layer. Once this rutile RuO₂ layer is generated on the surface (1 cycle), the film nucleation is enhanced and STO films can be grown more easily. Ozone is a strong oxidant to ruthenium, and can easily generate RuOx solid species, while H₂O will not. FIG. 1 illustrates that phenomenon, as strontium oxide deposition on Ru using ozone exhibit a much higher layer density than the water case at same temperature (below decomposition at 340° C.).

### Example 6

### BST Film Deposition Using Sr(CpiPr₃)₂, Ba(CpiPr₃)₂, and Ti(tmhd)₂(OiPr)₂

It is possible to use a similar barium precursor, Ba(CpiPr₃)₂, and add it to example 4 in order to obtain Barium Strontium Titanium oxide films (BST). The barium precursor may be placed in a canister and provided to the reaction chamber by bubbling mode. Ozone is used as the only co-reactant for the three precursors of barium, strontium, and titanium.

The pulse of each precursor may be repeated independently in order to obtain saturation and desired property of the films.

One example of total cycle is proposed as—(titanium-purge-ozone-purge)₅-strontium-purge-ozone-purge-barium-purge-ozone-purge-, and this cycle is repeated as many time as needed until the desired thickness is obtained.

As obtained in example 4, it is expected that a high ALD upper temperature will be obtained (compared to the low value obtained when H₂O is used)

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method for depositing a film onto one or more substrates, comprising:
a) providing a reactor, and at least one substrate disposed in the reactor;
b) providing at least one alkaline earth metal precursor and at least one titanium precursor, each dissolved or not in a solvent or solvent mixture, wherein:
1) the alkaline earth metal precursor comprises a precursor of the general formula:
M(RₘCp)₂Lₙ (I)
wherein:
M is strontium or barium
each R is independently selected from H, and a C1-C4 linear, branched, or cyclic alkyl group;
m is one of 2, 3, 4, or 5;
n is one of 0, 1 or 2; and
L is a Lewis base; and
2) The titanium precursor comprises at least one precursor selected from the group consisting of precursors with the general formulas:
Ti(OR)₂X₂ (II)
Ti(O)X₂ (III)
Ti(R′_{y}Cp)(OR″)₃ (IV)
wherein:
each R, R′, R″ is independently selected from H, and a C1-C4 linear, branched, or cyclic alkyl group;
X is a β-diketonate ligand, substituted or not on all the available substitution sites, each substitution site independently being substituted by one of a C1-C4 linear, branched, or cyclic alkyl group, or a C1-C4 linear, branched, or cyclic fluoroalkyl group (totally fluorinated or not); and
y is one of 1, 2, 3, 4, or 5;
c) vaporizing the alkaline earth metal precursor and the titanium precursor, together or independently, to form alkaline earth metal and titanium precursor vapor solutions;
d) introducing the at least part of the precursor vapor solutions into the reactor; and
e) depositing at least part of the precursor vapor solution onto the substrate to form a strontium titanium containing film or strontium barium titanium containing film.

2. The method of claim 1, further comprising providing at least one of the alkaline earth metal or titanium precursors in a solvent or solvent mixture, wherein the solvent or solvent mixture comprises an aromatic solvent with at least one aromatic ring, and wherein the aromatic solvent has a boiling point greater than the melting point of the alkaline earth metal or titanium precursor.

3. The method of claim 2, wherein the aromatic solvent comprises a solvent of the general formula:
CₐR_{b}N_{c}O_{d}
wherein:
each R is independently selected from: H; a C1-C6 linear, branched, or cyclic alkyl or aryl group; an amino substituent such as NR¹R² or NR¹R²R³, where R¹, R² and R³ are independently selected from H, and a C1-C6 linear, branched, or cyclic alkyl or aryl group; and an alkoxy substituent such as OR⁴, or OR⁵R⁶ where R⁴, R⁵ and R⁶ are independently selected from H, and a C1-C6 linear, branched, or cyclic alkyl or aryl group;
a is 4 or 6;
b is 4, 5, or 6;
c is 0 or 1; and
d is 0 or 1.

4. The method of claim 3, wherein the aromatic solvent comprises at least one member selected from the group consisting of: toluene; mesitylene; phenetol; octane; xylene; ethylbenzene; propylbenzene; ethyltoluene; ethoxybenzene; pyridine; and mixtures thereof.

5. The method of claim 1, wherein the Lewis base comprises at least one member selected from the group consisting of: tetrahydrofuran; dioxane; dimethoxyethane, diethoxyethane; and pyridine.

6. The method of claim 1, further comprising:
a) introducing an oxidizing gas into the reactor; and
b) reacting the oxidizing gas with at least part of the precursor vapor solutions prior to or concurrently with the deposition of at least part of the precursor vapor solutions onto the substrate.

7. The method of claim 6, wherein the oxidizing gas is ozone, its radical species, or any ozone containing mixture.

8. The method of claim 1, further comprising depositing at least part of the precursor vapor solutions through a chemical vapor deposition (CVD) or an atomic layer deposition (ALD) process.

9. The method of claim 8, wherein the deposition is performed at temperature between about 50° C. and about 600° C.

10. The method of claim 9, wherein the temperature is between about 200° C. and about 500° C.

11. The method of claim 8, wherein the deposition is performed at a pressure between about 0.0001 Torr and about 1000 Torr.

12. The method of claim 11, wherein the pressure is between about 0.1 Torr and about 10 Torr.

13. The method of claim 1, wherein the strontium precursor comprises at least one member selected from the group consisting of: Sr(iPr₃Cp)₂; Sr(iPr₃Cp)₂(THF); Sr(iPr₃Cp)₂(THF)₂; Sr(iPr₃Cp)₂(dimethylether); Sr(iPr₃Cp)₂(dimethylether)₂; Sr(iPr₃Cp)₂(diethylether); Sr(iPr₃Cp)₂(diethylether)₂; Sr(iPr₃Cp)₂(dimethoxyethane); Sr(iPr₃Cp)₂(dimethoxyethane)₂; Sr(tBu₃Cp)₂; Sr(tBu₃Cp)₂(THF); Sr(tBu₃Cp)₂(THF)₂; Sr(tBu₃Cp)₂(dimethylether); Sr(tBu₃Cp)₂(dimethylether)₂; Sr(tBu₃Cp)₂(diethylether); Sr(tBu₃Cp)₂(diethylether)₂; Sr(tBu₃Cp)₂(dimethoxyethane); and Sr(tBu₃Cp)₂(dimethoxyethane)₂.

14. The method of claim 1, wherein the barium precursor comprises at least one member selected from the group consisting of: Ba(iPr₃Cp)₂; Ba(iPr₃Cp)₂(THF); Ba(iPr₃Cp)₂(THF)₂; Ba(iPr₃Cp)₂(dimethylether); Ba(iPr₃Cp)₂(dimethylether)₂; Ba(iPr₃Cp)₂(diethylether); Ba(iPr₃Cp)₂(diethylether)₂; Ba(iPr₃Cp)₂(dimethoxyethane); Ba(iPr₃Cp)₂(dimethoxyethane)₂; Ba(tBu₃Cp)₂; Ba(tBu₃Cp)₂(THF); Ba(tBu₃Cp)₂(THF)₂; Ba(tBu₃Cp)₂(dimethylether); Ba(tBu₃Cp)₂(dimethylether)₂; Ba(tBu₃Cp)₂(diethylether); Ba(tBu₃Cp)₂(diethylether)₂; Ba(tBu₃Cp)₂(dimethoxyethane); and Ba(tBu₃Cp)₂(dimethoxyethane)₂.

15. The method of claim 1, wherein the titanium precursor comprises at least one member selected from the group consisting of: Ti(OMe)₂(acac)₂; Ti(OEt)₂(acac)₂; Ti(OPr)₂(acac)₂; Ti(OBu)₂(acac)₂; Ti(OMe)₂(tmhd)₂; Ti(OEt)₂(tmhd)₂; Ti(OPr)₂(tmhd)₂; Ti(OBu)₂(tmhd)₂; TiO(acac)₂; TiO(tmhd)₂; Ti(Me₅Cp)(OMe)₃; and Ti(MeCp)(OMe)₃.

16. A composition comprising: at least one alkaline earth metal precursor and at least one titanium precursor, each dissolved or not in a solvent or solvent mixture, wherein:
a) the alkaline earth metal precursor comprises a precursor of the general formula:
M(RₘCp)₂Lₙ (I)
wherein:
M is strontium or barium
each R is independently selected from H, and a C1-C4 linear, branched, or cyclic alkyl group;
m is one of 2, 3, 4, or 5;
n is one of 0, 1 or 2; and
L is a Lewis base; and
b) The titanium precursor comprises at least one precursor selected from the group consisting of precursors with the general formulas:
Ti(OR)₂X₂ (II)
Ti(O)X₂ (III)
Ti(R′_{y}Cp)(OR″)₃ (IV)
wherein:
each R, R′, R″ is independently selected from H, and a C1-C4 linear, branched, or cyclic alkyl group;
X is a β-diketonate ligand, substituted or not on all the available substitution sites, each substitution site independently being substituted by one of a C1-C4 linear, branched, or cyclic alkyl group, or a C1-C4 linear, branched, or cyclic fluoroalkyl group (totally fluorinated or not); and
y is one of 1, 2, 3, 4, or 5; and
c) the solvent or solvent mixture comprises an aromatic solvent with at least one aromatic ring, and the aromatic solvent has a boiling point greater than the melting point of the alkaline earth metal or titanium precursor.

17. The composition of claim 16, wherein the aromatic solvent comprises a solvent of the general formula:
CₐR_{b}N_{c}O_{d}
wherein:
each R is independently selected from: H; a C1-C6 linear, branched, or cyclic alkyl or aryl group; an amino substituent such as NR¹R² or NR¹R²R³, where R¹, R² and R³ are independently selected from H, and a C1-C6 linear, branched, or cyclic alkyl or aryl group; and an alkoxy substituent such as OR⁴, or OR⁵R⁶ where R⁴, R⁵ and R⁶ are independently selected from H, and a C1-C6 linear, branched, or cyclic alkyl or aryl group;
a is 4 or 6;
b is 4, 5, or 6;
c is 0 or 1; and
d is 0 or 1.

18. The composition of claim 17, wherein the aromatic solvent comprises at least one member selected from the group consisting of: toluene; mesitylene; phenetol; octane; xylene; ethylbenzene; propylbenzene; ethyltoluene; ethoxybenzene; pyridine; and mixtures thereof.

19. The composition of claim 16, wherein the Lewis base comprises at least one member selected from the group consisting of: tetrahydrofuran; dioxane; dimethoxyethane, diethoxyethane; and pyridine.

20. The composition of claim 16, wherein the strontium precursor comprises at least one member selected from the group consisting of: Sr(iPr₃Cp)₂; Sr(iPr₃Cp)₂(THF); Sr(iPr₃Cp)₂(THF)₂; Sr(iPr₃Cp)₂(dimethylether); Sr(iPr₃Cp)₂(dimethylether)₂; Sr(iPr₃Cp)₂(diethylether); Sr(iPr₃Cp)₂(diethylether)₂; Sr(iPr₃Cp)₂(dimethoxyethane); Sr(iPr₃Cp)₂(dimethoxyethane)₂; Sr(tBu₃Cp)₂; Sr(tBu₃Cp)₂(THF); Sr(tBu₃Cp)₂(THF)₂; Sr(tBu₃Cp)₂(dimethylether); Sr(tBu₃Cp)₂(dimethylether)₂; Sr(tBu₃Cp)₂(diethylether); Sr(tBu₃Cp)₂(diethylether)₂; Sr(tBu₃Cp)₂(dimethoxyethane); and Sr(tBu₃Cp)₂(dimethoxyethane)₂.

21. The composition of claim 16, wherein the barium precursor comprises at least one member selected from the group consisting of: Ba(iPr₃Cp)₂; Ba(iPr₃Cp)₂(THF); Ba(iPr₃Cp)₂(THF)₂; Ba(iPr₃Cp)₂(dimethylether); Ba(iPr₃Cp)₂(dimethylether)₂; Ba(iPr₃Cp)₂(diethylether); Ba(iPr₃Cp)₂(diethylether)₂; Ba(iPr₃Cp)₂(dimethoxyethane); Ba(iPr₃Cp)₂(dimethoxyethane)₂; Ba(tBu₃Cp)₂; Ba(tBu₃Cp)₂(THF); Ba(tBu₃Cp)₂(THF)₂; Ba(tBu₃Cp)₂(dimethylether); Ba(tBu₃Cp)₂(dimethylether)₂; Ba(tBu₃Cp)₂(diethylether); Ba(tBu₃Cp)₂(diethylether)₂; Ba(tBu₃Cp)₂(dimethoxyethane); and Ba(tBu₃Cp)₂(dimethoxyethane)₂.

22. The composition of claim 15, wherein the titanium precursor comprises at least one member selected from the group consisting of: Ti(OMe)₂(acac)₂; Ti(OEt)₂(acac)₂; Ti(OPr)₂(acac)₂; Ti(OBu)₂(acac)₂; Ti(OMe)₂(tmhd)₂; Ti(OEt)₂(tmhd)₂; Ti(OPr)₂(tmhd)₂; Ti(OBu)₂(tmhd)₂; TiO(acac)₂; TiO(tmhd)₂; Ti(Me₅Cp)(OMe)₃; and Ti(MeCp)(OMe)₃.

23. A strontium and titanium-containing thin film-coated substrate or a strontium barium titanium containing thin film coated substrate comprising the product of the process of claim 1.
